(19) United States
(12) Patent Application Publication
(10) Pub. No.: US 2005/0196961 A1
(43) Pub. Date: Sep. 8, 2005

(54) Method for forming a semiconductor device having metal silicide

(76) Inventors: Da Zhang, Austin, TX (US); Olubunmi O. Adetutu, Austin, TX (US); Shahid Rauf, Pflugerville, TX (US); Peter L. G. Ventzek, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/795,847

(22) Filed: Mar. 8, 2004

(51) Int. Cl. H01L 21/44; H01L 21/4763; H01L 21/336

(52) U.S. Cl. 438/655; 438/649; 438/664; 438/305

(57) ABSTRACT

In one embodiment, a top surface of a semiconductor device (18) is amorphized in a tool (1). A metal is deposited over the semiconductor substrate using the same tool. In one embodiment, the same chambers are used. In an embodiment, the tool is a sputtering tool, such as a physical vapor deposition (PVD). The semiconductor substrate may be annealed to form a metal silicide (122) over at least a portion of the semiconductor device that includes silicon.

### FIELD OF THE INVENTION

The field of the invention relates generally to semiconductor devices, and more specifically, to forming metal suicide on a semiconductor device.

### BACKGROUND OF THE INVENTION

Typically, metal silicides, such as nickel silicide and cobalt silicide, are formed over the source region, drain region, and polysilicon gate electrodes to enhance adhesion and reduce contact resistance. The metal silicides are formed by depositing a layer of metal, such as nickel or cobalt, on a top surface of the semiconductor device after the transistor has been formed. An anneal is performed to react the deposited metal with the silicon-containing regions of the top surface of the semiconductor device and form the metal silicide. Any region that does not include silicon (e.g., a spacer dielectric region) will not form a metal silicide. Hence, the process is selective in that metal suicides are only formed on regions that include silicon.

When the regions that include silicon are crystalline, increased processing is often performed to enhance the desired contact properties in the resulting metal silicide. An amorphization process is one efficient enhancement approach. Amorphization occurs by using high energy ions to bombard the semiconductor device and change the structure of the crystalline silicon regions.

### BRIEF DESCRIPTION OF THE DRAWINGS

The present invention is illustrated by way of example and not limited by the accompanying figures, in which like references indicate similar elements, and in which:

FIG. 1 illustrates a control system including an ionizing physical vapor depositing system (iPVD), a metrology tool, a computer, and power supplies in accordance with one embodiment of the present invention;

FIG. 2 illustrates a cross-section of a portion of a semiconductor device before processing the semiconductor device using the control system of FIG. 1 in accordance with one embodiment of the present invention; and

FIG. 3 illustrates the semiconductor device of FIG. 2 after processing the semiconductor device using the control system of FIG. 1 in accordance with one embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

One tool can be used to perform both the amorphization and metal deposition processes by operating the tool in distinct process regimes. Using one tool can decrease the cost of the metal silicidation process because only one tool, not two different tools, are needed. Preferably, the same chamber is used for both processes. Cycling time is decreased because the semiconductor device need not be transferred from one tool or chamber to another. Yield may increase because the risk of the semiconductor device being damaged during the transfer from one tool to another is eradicated.

Any plasma system in which decoupled power sources for driving metal deposition and ion bombardment to the semiconductor device 18 are present can be used. In one embodiment, a PVD system having only target, driven with direct current (DC), radio frequency (RF), or other frequency power, and substrate bias power supplies is used, such as a self-ionized plasma (SIP). In another embodiment, the tool that is used for amorphization and metal deposition process is an ionizing physical vapor deposition (iPVD) system having a coil power, a target power, and a substrate bias power supply. In addition, other tools that can create and maintain a plasma can be used, such as a tool having a biased ECR (electron cyclotron resonance) or microwave driven sources.

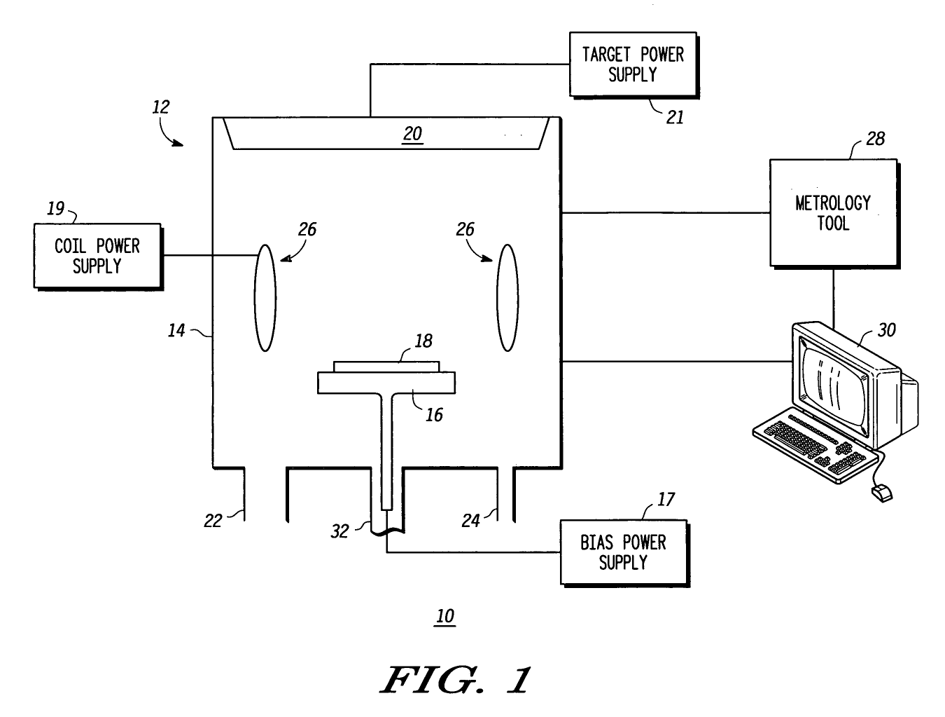

FIG. 1 illustrates a control system 10 including an iPVD system (sputtering system) 12 connected to power supplies 17, 19 and 21. In one embodiment, the control system optionally includes a metrology tool 28 and a computer 30.

The power supplies include a substrate bias power supply 17, a coil power supply 19, and a target power supply 21. When power is applied to a sputtering target 20 by the target power supply 21, which in one embodiment is a DC power supply, a voltage differential is created between the sputtering target which is negatively charged (cathode) and the remainder of the chamber. Additionally, bias power can be applied to a wafer chuck 16 from the bias power supply 17. The wafer chuck 16 is coupled to the bias power supply 17 and sputtering target is coupled to the target power supply 21. In one embodiment, the bias power supply 17 is an AC power supply. The coil power supply 19 is coupled to and provides power to coils 26. In one embodiment, the coil power supply 19 is an AC power supply.

The iPVD system 12 includes a semiconductor device 18 positioned on a wafer chuck 16 located near one side (e.g. the bottom) of a sputtering chamber 14, a sputtering target 20 located near another side of the sputtering chamber 14 and coils 26 located near the vertical sides of the chamber. The sputtering chamber 14 may be made of a non-magnetic material, (such as non-magnetic stainless steel), or aluminum or titanium, and has a pumping port 22 that is used to pump the atmosphere in the sputtering chamber 14 to vacuum. In one embodiment, the sputtering chamber 14 is made of stainless steel and any shields inside the chamber are made of stainless steel, aluminum or titanium. The power supplied to coils 26 sustains a plasma inside the chamber. In one embodiment, a faraday shield or similar structure (not shown) may be present to cover the coils 26 to prevent deposition on the coils and coil re-sputtering. The structure may have openings for power deposition into the plasma region between the coils 26.

The sputtering chamber 14 also has a gas inlet 24, which supplies gas used for sputtering, and a chuck feed through 32, which accommodates supplies for the wafer chuck 16, e.g., cooling water, a thermocouple, and a power supply for substrate biasing and/or an electrostatic chuck. The wafer chuck 16 supports the semiconductor device 18 within the sputtering chamber 14.

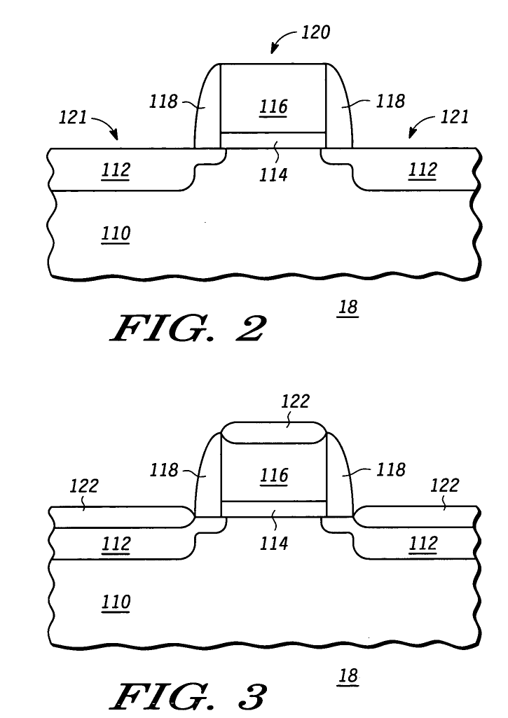

In one embodiment, the semiconductor device 18 includes the structure of semiconductor device 18 in FIG. 2. The semiconductor device 18 has a semiconductor substrate 110, source/drain regions 112 formed within the semiconductor substrate 110, a gate dielectric 114 formed over the semiconductor substrate 110 and between the source/drain regions 112, a gate electrode 116 formed over the gate dielectric 114, and (sidewall) spacers 118 adjacent and, in one embodiment, in contact with the sidewalls of the gate dielectric 114 and the gate electrode 116. A skilled artisan should recognize that the processes for forming the structures just described in FIG. 2 are well known. Furthermore, the structure of the semiconductor device 18 may differ from that shown but still be a transistor. For example, additional sidewall spacers, liner, or doped regions (e.g., halo regions) may be present. The structure in FIG. 2 is illustrative only and the metal silicidation process to be discussed below can be used on any semiconductor structure where metal silicidation is desired; the process is not limited to the device structure shown in FIG. 2.

The semiconductor substrate 110 can be silicon, silicon germanium, gallium arsenide, silicon on insulator (SOI), any other III-V material, or a combination of the above. The source/drain regions 112 may be the same material as the semiconductor substrate 110 but are doped either n-type or p-type. If the source/drain regions 112 include silicon then a metal silicide will be formed on a top source/drain surface 121 of the semiconductor substrate 110 through the metal silicidation process. The gate dielectric 114 may be any dielectric material, such as silicon dioxide, a high dielectric constant (high-k) material (e.g., hafnium oxide, zirconium oxide), the like and combinations of the above. In one embodiment, the gate electrode 116 includes silicon (e.g., polysilicon), a metal silicide will subsequently be formed over a top exposed surface 120. In another embodiment, the gate electrode 116 includes a metal. If the gate electrode 116 does not include silicon, then a metal suicide will not be formed over the top exposed surface 120.

In one embodiment, the semiconductor device 18 of FIG. 2 is placed in a deposition tool, such as the iPVD system 12 to begin the metal silicidation process. More specifically, in one embodiment the semiconductor device 18 is placed into a load lock (not shown) in which the pressure is pumped down to vacuum. In this embodiment, once vacuum is reached the semiconductor device 18 is transferred (in one embodiment, by a robotic arm) into the sputtering chamber 14, which has previously been pumped down to vacuum using the pumping port 22.

In one embodiment, the semiconductor device 18 is directly opposite and coplanar with the sputtering target 20. In another embodiment, the sputtering target 20 is on a sidewall of the sputtering chamber 14 and is angled towards the semiconductor device 18. In yet another embodiment, more than one sputtering target is used and the sputtering targets can be in any configuration (e.g. directly opposite and coplanar with the semiconductor device 18 and/or on the sidewall of the sputtering chamber 14). The sputtering target 20 includes one to all components of the material to be sputtered onto the semiconductor device 18. (If more than one sputtering target 14 is present in the sputtering chamber 14, the material to be deposited may be a combination of the materials on the targets.)

First, the amorphization phase of the metal silicidation process is performed. Amorphizing occurs when a region, which may be substantially crystalline, becomes substantially amorphous. In the sputtering chamber 14, a an inert gas, such as argon, helium, xenon, or a non-inert gas, such as germanium-containing gas, is introduced into the sputtering chamber 14 via the gas inlet 24 to produce a plasma. Neutral atoms are ionized (in one embodiment, by a cosmic ray) giving off electrons and ions. Ionization of the source gas takes place in the plasma region.

In order to amorphize the semiconductor device 18, in one embodiment, ions will bombard the semiconductor device 18, but no or minimal deposition on the semiconductor device 18 should occur. Since deposition tools, such as iPVD tools, are used to deposit materials, using the tool to do something while preventing or minimizing deposition is counter to the tool's normal function. To prevent metal deposition (i.e., to prevent target sputtering when using a PVD tool, such as an iPVD tool), the target power supply 21 should be shut off or set to a low value (i.e., substantially off). In one embodiment, the target power supply 21 should be less than approximately 200 Watts. Other means of preventing material from the sputtering target 20 or the coils 26 from impinging the semiconductor device 18 include providing a DC bias to the sputtering target 20 and the coils 26. It is desirable that a positive DC biasing of the sputtering target 20 and the coils is applied to avoid ion bombardment from the sputtering target 20 and the coils 26. Magnetic insulation of walls or other material surfaces in the chamber may be necessary provided the sheath voltage at those surfaces is low enough to inhibit sputtering and subsequent deposition of material on the semiconductor device 18.

To create ions in a plasma, which will interact with the semiconductor device 18 and change the structure of the top surfaces 120 and 121 of the semiconductor device 18, the coil power and bias power should be on. In one embodiment, the coil power is between approximately 500 Watts to approximately 2 kilowatts, or more specifically, approximately 1 kilowatt, and the bias power is greater than approximately 1 kilowatt. The high bias power induces high energies so that the ionized species strike the semiconductor device 18, which causes the top surfaces 120 and 121 to be amorphized.

A skilled artisan recognizes that these values may change based on the tool being used, especially if a different manufacturer of an iPVD tool is used. The above values have been chosen for Applied Materials' (AMAT's) Endura IMP-PVD tool; however, any other suitable tool may be used.

After amorphization of the top surfaces 120 and 121, the metal is deposited. The semiconductor device 18 may remain in the chamber under vacuum, which increases cycle time. Alternatively, the semiconductor device 18 may be changed to another chamber within the same tool, if desired. To deposit the metal on the semiconductor device 18 the parameters of the iPVD system 12 are modified so that deposition will occur.

Through the gas inlet 24, a gas source, such as argon, helium, or xenon continues to be introduced into the sputtering chamber 14. The gas can be the same as that used during amorphization; alternatively, a different gas may be used. The target power supply 21 increases the power supplied to the sputtering target 20. In one embodiment, the target power is between approximately 500 Watts and approximately 6 kilowatts. The bias power is turned off or low, preferably less than approximately 200 Watts. The coil power is turned on, which in one embodiment is between approximately 500 Watts to approximately 2 kiloWatts.

A voltage differential exists between the sputtering target 20, which is negatively charged (cathode), and the remainder of the chamber. In one embodiment, the sputtering target 20 include nickel, cobalt, another metal, the like, or combinations of the above. As discussed above, electrons, ionized species, and neutral gas atoms are created. The ionized species, which are positively charged, are attracted to and therefore accelerated towards the sputtering target 20 (negatively charged). The magnitude of the voltage differential in the sputtering chamber controls the force with which the positive ions are attracted to the sputtering target 20. Upon impact with the sputtering target 20, the energetic ions dislodge and eject atoms from the sputtering target 20. (Some energy from the ions may be transferred to the sputtering target 14 in the form of heat.) The dislodged target material travels through the vacuum medium to the semiconductor device 18 to form a sputtered layer with other identical, similar or different atoms and/or materials already on the semiconductor device 18. A magnetic field may be present in the sputtering chamber 14 and it can be controlled by electromagnets that lie about the sputtering chamber 14.

After some of the material from sputtering target 20 is deposited on the semiconductor device 18, the semiconductor device 18 is removed from the iPVD system 12, in one embodiment using a robotic arm and human actions, serially, to an anneal tool. The semiconductor device 18 then goes through a first anneal so that the deposited material will react with the top surfaces 120 and 121 that include silicon. All other areas that have been covered with the metal, such as the surfaces of the spacers 118 will not react with the metal during the anneal process and therefore no metal silicide will be formed. After the first anneal, a clean is performed to remove any unreacted metal. In one embodiment, the clean is a selective etch process. Optionally, a second anneal is performed after the clean step to optimize silicide properties. In one embodiment, the first anneal occurs at approximately 340° C. for about 30 sec, the clean can be done using a wet etchant, such as a mixture of hydrogen peroxide and nitric or sulfuric acid, and the second anneal occurs at approximately 450° C. for about 30 sec.

The resulting semiconductor device 18 is shown in FIG. 3. After the anneal process and the clean metal silicide regions 122 are formed over the source/drain regions 112 and the gate electrode 116, presuming these regions include silicon. Any region that doesn't include silicon will not have a metal silicide region 122 formed over it. For example, if the gate electrode 116 is a metal without the presence of silicon (e.g., a TiN metal gate), the metal silicide region 122 over the gate electrode 116 would not be formed.

In the foregoing specification, the invention has been described with reference to specific embodiments. However, one of ordinary skill in the art appreciates that various modifications and changes can be made without departing from the scope of the present invention as set forth in the claims below. For example, any ionized sputtering system or deposition tool can be used. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method for forming a semiconductor device comprising:
providing a semiconductor substrate;
forming a source region and a drain region within the semiconductor substrate, wherein the source region has a first top surface and the drain region has a second top surface;
forming a gate dielectric over the semiconductor substrate and between the source region and the drain region;
forming a gate electrode over the gate dielectric, wherein the gate electrode has a third top surface;
amorphizing a portion of the semiconductor device selected from a group consisting of the first top surface, the second top surface and the third top surface, wherein the amorphizing is performed in a chamber;
depositing a metal over the semiconductor substrate in the chamber; and
annealing the semiconductor substrate to form a metal silicide over a portion of the semiconductor device selected from a group consisting of the first top surface, the second top surface, and the third top surface.

2. The method of claim 1, wherein amorphizing and depositing the metal further comprise using a physical vapor deposition system.

3. The method of claim 1, wherein depositing the metal further comprises sputtering a metal.

4. The method of claim 1, wherein amorphizing further comprises turning the target power substantially off.

5. The method of claim 1, wherein amorphizing a portion of the semiconductor device selected from a group consisting of the first top surface, the second top surface and the third top surface, further comprises amorphizing the first top surface, the second top surface and the third top surface.

6. The method of claim 5, wherein annealing the semiconductor substrate to form a metal silicide over a portion of the semiconductor device selected from a group consisting of the first top surface, the second top surface, and the third top surface further comprises forming a metal suicide over the first top surface and the second top surface.

7. The method of claim 1, wherein annealing the semiconductor substrate to form a metal silicide over a portion of the semiconductor device selected from a group consisting of the first top surface, the second top surface, and the third top surface further comprises forming a metal silicide over the first top surface, the second top surface and the third top surface.

8. The method of claim 1, wherein annealing the semiconductor substrate to form a metal suicide further comprises forming non-reacted metal, and the method of claim 1 further comprises:
removing the non-reacted metal; and
annealing the semiconductor substrate after removing the non-reacted metal.

9. A method for forming a semiconductor device comprising:
providing a semiconductor substrate having a top surface comprising silicon;
amorphizing the top surface of the semiconductor substrate using a sputtering system, wherein the sputtering system comprises a sputtering target; and
setting the target power of the sputtering system so that substantially no power is supplied to the sputtering target.

10. The method of claim 9, wherein amorphizing further comprises bombarding the top surface of the semiconductor substrate with ions in a physical vapor deposition system.

11. The method of claim 9, further comprising:
sputtering a metal on the top surface using the sputtering system; and
reacting the metal with the top surface to form a metal silicide.

12. A method for forming a semiconductor device comprising:
providing a semiconductor substrate having a top surface;
bombarding the top surface of the semiconductor substrate with ions to alter the material structure of at least a portion of the top surface using a deposition system;
depositing a metal over the top surface; and
reacting the metal with the top surface.

13. The method of claim 12, wherein depositing the metal over the top surface further comprises depositing the metal over the top surface using the deposition system.

14. The method of claim 13, wherein depositing the metal and bombarding the top surface occur in the same chamber.

15. The method of claim 12, wherein reacting the metal further comprises annealing the semiconductor substrate.

16. A method of forming a semiconductor device comprising:
providing a semiconductor substrate comprising a crystalline portion, wherein the crystalline portion comprises silicon;
changing the crystalline portion to an amorphous portion using a chamber in a deposition tool; and
depositing a metal on the amorphous portion in the deposition tool.

17. The method of claim 16, further comprising:
reacting the metal with the amorphous portion to form a metal silicide.

18. The method of claim 16, wherein depositing the metal further comprises depositing the metal in the chamber.

19. The method of claim 16, wherein changing the crystalline portion to an amorphous portion further comprises bombarding the crystalline portion with ions.

20. The method of claim 16, wherein depositing the metal further comprises depositing a metal selected from the group consisting of cobalt and nickel.

21. The method of claim 16, wherein the depositing tool is a sputtering tool.
